(19) United States
(12) Patent Application Publication
(10) Pub. No.: US 2013/0206069 A1
(43) Pub. Date: Aug. 15, 2013

(54) DEPOSITION APPARATUS

(71) Applicant: ASM IP Holding B.V., (US)

(72) Inventor: Soo Hyun KIM, Ansan-si (KR)

(73) Assignee: ASM IP Holding B.V., Almere (NL)

(21) Appl. No.: 13/761,331

(22) Filed: Feb. 7, 2013

(30) Foreign Application Priority Data
Feb. 10, 2012 (KR) 10-2012-0013786

(51) Int. Cl. C23C 16/458

(52) U.S. Cl. CPC C23C 16/458
USPC 118/723 R; 118/728

(57) ABSTRACT

In a deposition apparatus, a coming-off prevention unit is formed on the side surface of a substrate supporting pin to prevent the substrate supporting pin from being separated from the deposition apparatus even if the substrate supporting pin sticking on the substrate due to static electricity occurring during the deposition process is moved. Therefore, damage of the substrate supporting pin or the substrate, which may occur when the substrate supporting pin comes off, can be prevented. Further, as a rod is inserted into a hole formed in the substrate supporting pin, the substrate supporting pin is prevented from coming off from a motion path, when the substrate supporting pin is moved in a vertical direction. Accordingly, damage of the substrate supporting pin, which may occur when the substrate supporting pin comes off during the vertical motion, can be prevented.

### CROSS-REFERENCE TO RELATED APPLICATION

This application claims priority to and the benefit of Korean Patent Application No. 10-2012-0013786 filed in the Korean Intellectual Property Office on Feb. 10, 2012, the entire contents of which are incorporated herein by reference.

### BACKGROUND OF THE INVENTION

(a) Field of the Invention

The present invention relates to a deposition apparatus.

(b) Description of the Related Art

During a deposition process using plasma, static electricity may occur in a substrate on which a thin film is deposited. When the substrate is removed from the susceptor after the process, a substrate supporting pin may stick on the rear surface of the substrate due to the static electricity. In this case, the substrate supporting pin may interfere with the motion of the substrate or may be damaged, or the substrate may be damaged.

In order to solve such a problem, Korean Patent Application Laid-Open No. 10-2006-0068132 has disclosed a method for discharging static electricity through a lower plate to support a gold-plated substrate supporting pin. Further, Korean Patent Application Laid-Open No. 10-2007-0008975 has disclosed a method for preventing damage of a substrate or substrate supporting pin by discharging static electricity through a lift hoop supporting the substrate supporting pin having a metal rod inserted therein, the static electricity occurring while the discharging process is performed.

However, even if such a structure is used, discharging of static electricity may not be performed when an unnecessary thin film, in particular an oxide thin film, is formed between the supporting pin and a plate or the lift hoop supporting the supporting pin while the process is performed multiple times.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a deposition apparatus capable of preventing a substrate supporting pin from coming off from a unit for supporting the substrate supporting pin even when static electricity occurs during a plasma process, such that the substrate supporting pin or the substrate is not damaged.

Further, the present invention has been made in an effort to provide a deposition apparatus capable of preventing a substrate supporting pin from coming off from a vertical motion path even when a substrate supporting pin moves in a vertical direction, such that the substrate supporting pin is not damaged.

An exemplary embodiment of the present invention provides a deposition apparatus including: a substrate support; a substrate supporting pin inserted into a hole formed in the substrates support; a coming-off prevention unit formed on a side surface of the substrate supporting pin; and a supporting plate supporting the substrate supporting pin.

According to various exemplary embodiments of the present invention:

the coming-off prevention unit may be disposed under the substrate support;

the deposition apparatus may further include an auxiliary unit formed on the coming-off prevention unit;

the auxiliary unit may further include an elastic body;

the auxiliary unit may further include a spring; and/or

the substrate supporting pin may have a hole formed therein, and a rod connected to the supporting plate may be inserted into the hole of the substrate supporting pin.

In one exemplary embodiment of the present invention, the deposition apparatus may further include a reaction chamber plate defining a reaction space together with the substrate support; and a high-frequency connection terminal for supplying plasma power to the reaction chamber plate.

In the deposition apparatus according to another exemplary embodiment of the present invention, the coming-off prevention unit is formed on the side surface of the substrate supporting pin to prevent the substrate supporting pin from being separated from the deposition apparatus. Accordingly, although the substrate supporting pin sticking on the substrate due to static electricity occurring during the deposition process is moved, the substrate supporting pin is prevented from coming off from the deposition apparatus. Therefore, damage of the substrate supporting pin or the substrate, which may occur when the substrate supporting pin comes off, can be prevented in the inventive deposition apparatus.

Further, as the rod is inserted into the hole formed in the substrate supporting pin, the substrate supporting pin is prevented from coming off from the moving path even when the substrate supporting pin is moved in the vertical direction. Accordingly, damage of the substrate supporting pin, which may occur when the substrate supporting pin comes off during the vertical motion, can be prevented in the inventive deposition apparatus.

### BRIEF DESCRIPTION OF THE DRAWINGS

FIG. 1 is a cross-sectional view of a deposition apparatus according to an exemplary embodiment of the present invention.

FIGS. 2 and 3 are cross-sectional views of a part of the deposition apparatus illustrated in FIG. 1.

FIG. 4 is a cross-sectional view of a part of a deposition apparatus according to another exemplary embodiment of the present invention.

FIGS. 5 and 6 are cross-sectional views of a part of a deposition apparatus according to yet another exemplary embodiment of the present invention.

FIGS. 7 and 8 are diagrams illustrating substrate supporting pins of the deposition apparatus according to the exemplary embodiments of the present invention.

### DETAILED DESCRIPTION OF THE EXEMPLARY EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., may have been exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

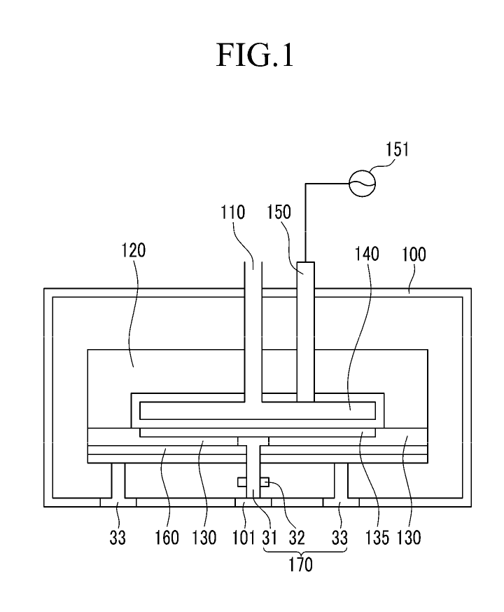

First, referring to FIG. 1, a deposition apparatus according to an exemplary embodiment of the present invention will be described. FIG. 1 is a cross-sectional view of a deposition apparatus according to an exemplary embodiment of the present invention.

Referring to FIG. 1, the deposition apparatus according to the exemplary embodiment of the present invention includes an outer wall 100, a gas path tube 110, a reaction chamber wall 120, a substrate support 130, a reaction chamber plate 140, a high-frequency connection terminal 150, and a high-frequency power supply 151. The substrate support 130 and the reaction chamber plate 140 together define a reaction space. The high-frequency connection terminal 150 transfers high-frequency power to the reaction chamber plate 140, in order to induce plasma in the reaction chamber. The high-frequency power supply 151 is connected to the high-frequency connection terminal 150.

The respective constituent elements will be described in more detail.

A substrate 135 is disposed as a deposition target on the substrate support 130, and a heating plate 160 is disposed under the substrate support 130. The heating plate 160 serves to increase the temperature of the substrate 135 to a temperature required for the process, and may be omitted.

A substrate support driver 170 for driving the substrate support 130 to attach and detach the substrate 135 includes a substrate supporting pin 31, a coming-off prevention unit 32, and a vertical motion driving unit 33. The substrate supporting pin 31 is inserted into a hole formed in the substrate support 130 so as to support the substrate 135. The coming-off prevention unit 32 serves to prevent the substrate supporting pin 31 from coming off outside. The vertical motion driving unit 33 serves to control vertical motion of the substrate support 130. The vertical motion driving unit 33 may include various units for controlling the vertical motion of the substrate support 130, such as a pneumatic cylinder, for example. The substrate supporting pin 31 may be supported by a supporting plate 101 formed under the substrate supporting pin 31.

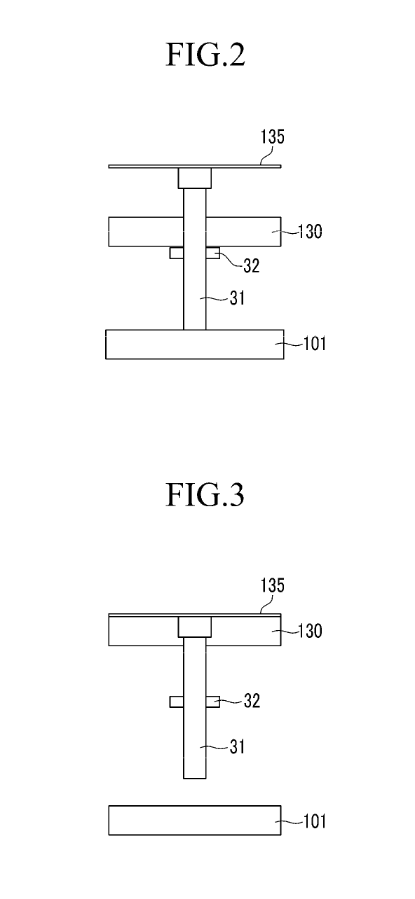

Referring to FIGS. 2 and 3, the vertical motion of the substrate support 130 for loading and unloading the substrate 135 will be described. FIGS. 2 and 3 are cross-sectional views of a part of the deposition apparatus exemplified in FIG. 1. FIG. 2 illustrates a configuration of the part of the deposition apparatus which is in a state before and after a deposition process, and FIG. 3 illustrates a configuration of the part of the deposition apparatus during the deposition process.

Referring to FIG. 2, the substrate support 130 (and the heating plate 160) connected to the vertical motion driving unit 33 moves downward to separate the reaction chamber wall 120 and the substrate support 130 from each other, before and after the deposition process. Then, the reaction chamber may be opened to load the substrate 135 in the reaction chamber or unload the substrate 135 from the reaction chamber. In this case, the substrate supporting pin 31 may be lifted or lowered by the vertical motion of the supporting plate 101 to unload the substrate 135 from the substrate support 130 or load the substrate 130 on the substrate support 130.

In the deposition apparatus according to the exemplary embodiment of the present invention, the coming-off prevention unit 32 is formed on the side surface of the substrate supporting pin 31 as illustrated in FIGS. 2 and 3. Therefore, after the deposition process is completed, although the substrate supporting pin 31 sticks to the rear surface of the substrate 135 due to static electricity accumulated on the substrate 135 such that the substrate supporting pin 31 moves upwards along with the substrate 135 while the substrate 135 is unloaded from the susceptor, the coming-off prevention unit 32 formed on the side surface of the substrate supporting pin 31 prevents the substrate supporting pin 31 from being moved over a level at which the substrate support 130 and the coming-off prevention unit 32 come in contact with each other. As a result, even though static electricity occurs, the substrate supporting pin 31 does not come off from the substrate support 130. Accordingly, damage of the substrate supporting pin 31 or the substrate 135, which may occur when the substrate supporting pin 31 comes off, can be prevented.

In particular, the coming-off prevention unit 32 of the deposition apparatus according to the exemplary embodiment of the present invention may physically prevent the substrate supporting pin 31 from coming off from the substrate support 130, regardless of whether an undesired thin film is deposited between the substrate supporting pin 31 and the substrate support 130, that is, even though static electricity occurs in the reaction chamber and is then transmitted to the substrate supporting pin 31.

The substrate support 130 and the substrate supporting pin 31 may move in a vertical direction such that the substrate support 130 and the coming-off prevention unit 32 have a predetermined distance, for example, about 5 mm. Therefore, when the substrate 135 is unloaded or loaded, the coming-off prevention unit 32 and the substrate support 130 do not contact with each other. Further, when the substrate supporting pin 31 is undesirably moved in the motion direction of the substrate 135 due to static electricity, the substrate support 130 and the coming-off prevention unit 32 come in contact with each other, thereby preventing the substrate supporting pin 31 from being moved along the substrate 135.

Referring to FIG. 3, the supporting plate 101 and the substrate supporting pin 31 are separated from each other during the deposition process, and the substrate supporting pin 31 is lowered to mount the substrate 135 on the substrate support 130. Then, the substrate support 130 and the heating plate 160 connected to the vertical motion driving unit 33 are moved upward, and the bottom of the reaction chamber wall 120 and the top of the substrate support 130 are closely attached to define the reaction chamber.

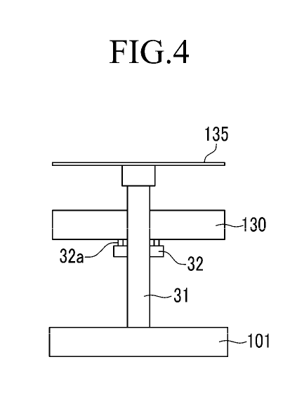

Referring to FIGS. 1 and 4, a deposition apparatus according to another exemplary embodiment of the present invention will be described. FIG. 4 is a cross-sectional view of a part of the deposition apparatus according to another exemplary embodiment of the present invention.

Referring to FIG. 4, the deposition apparatus according to the exemplary embodiment has almost the same structure as the deposition apparatus described with reference to FIGS. 1 to 3. However, in the deposition apparatus according to the exemplary embodiment described referring to FIG. 4, an auxiliary unit 32a is formed on the coming-off prevention unit 32 formed on the side surface of the substrate supporting pin 31. The auxiliary unit 32a may include a material having an elastic force, such as a spring. The auxiliary unit 32a may include all kinds of impact prevention units, in addition to the material having an elastic force.

When the substrate supporting pin 31 sticks on the substrate 135 due to static electricity and is moved in the moving direction of the substrate 135, the coming-off prevention unit 32 and the substrate support 130 may come in contact with each other. In this case, the auxiliary unit 32a may prevent an impact transmitted to the substrate supporting pin 31. Accordingly, when the substrate support 130 comes in contact with the coming-off prevention unit 32 formed on the substrate supporting pin 31, the substrate supporting pin 31 may be prevented from being damaged. Further, when the substrate 135 sticking on the substrate supporting pin 31 due to static electricity is separated from the substrate supporting pin 31 by the coming-off prevention unit 32, the impact transmitted to the substrate 135 may be relieved to prevent the substrate 135 from being damaged and coming off.

All of the features of the deposition apparatus described with reference to FIGS. 1 to 3 may also be applied to the deposition apparatus according to the exemplary embodiment described referring to FIG. 4.

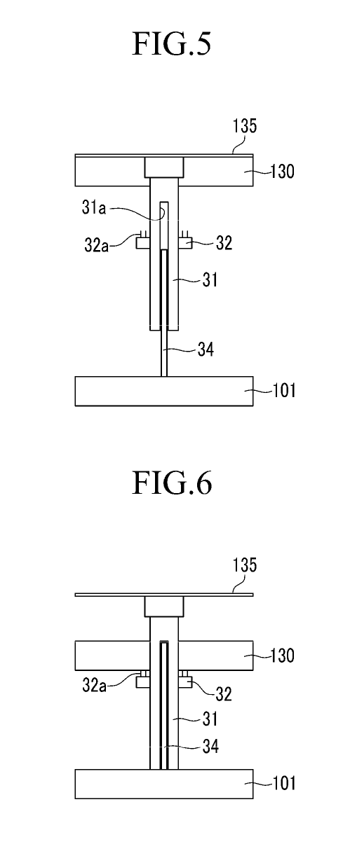

Referring to FIGS. 1, 5, and 6, a deposition apparatus according to yet another exemplary embodiment of the present invention will be described. FIGS. 5 and 6 are cross-sectional views of a part of a deposition apparatus according to yet another exemplary embodiment of the present invention.

Referring to FIGS. 5 and 6, the deposition apparatus according to the exemplary embodiment has almost the same structure as the deposition apparatus described with reference to FIGS. 1 to 3.

However, in the deposition apparatus according to the exemplary embodiment described referring to FIGS. 5 and 6, the substrate supporting pin 31 has a hole 31a formed therein, and a rod 34 connected to the supporting plate 101 is inserted into the hole 31a. As such, in the deposition apparatus according to the exemplary embodiment, the hole 31a is formed in the substrate supporting pin 31 and the rod 34 connected to the supporting plate 101 is inserted into the hole 31a, thereby fixing the vertical motion direction of the substrate supporting pin 31 while the substrate supporting pin 31 is vertically moved. That is, the rod 34 inserted into the hole 31a may prevent the substrate supporting pin 31 from being moved leftward and rightward when the substrate supporting pin 31 is vertically moved. Therefore, when the substrate supporting pin 31 is vertically moved, the substrate supporting pin 31 may be prevented from unnecessarily coming off from the substrate support 130.

Further, as the deposition apparatus according to the exemplary embodiment includes the coming-off prevention unit 32 formed on the side surface of the substrate supporting pin 31 like the deposition apparatuses according to the above-described exemplary embodiments, the substrate supporting pin 31 may be prevented from coming off from the substrate support 130 due to static electricity.

All of the features of the deposition apparatuses according to the exemplary embodiments described with reference to FIGS. 1 to 4 may be applied to the deposition apparatus according to the exemplary embodiment described referring to FIGS. 5 and 6.

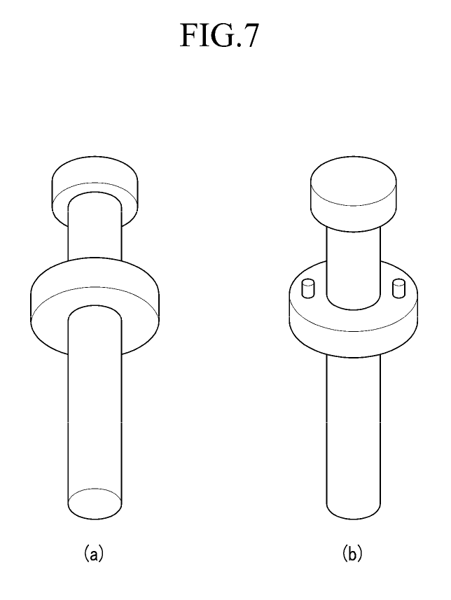

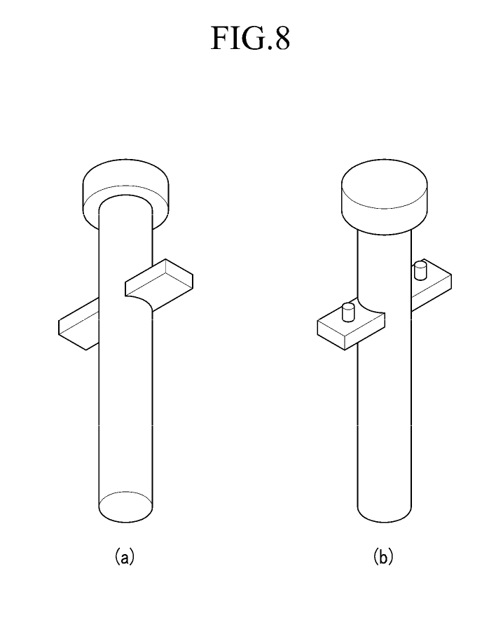

Referring to FIGS. 7 and 8, various shapes of substrate supporting pins of the deposition apparatus according to the exemplary embodiment of the present invention will be described. FIGS. 7 and 8 are diagrams illustrating the substrate supporting pins of the deposition apparatus according to the exemplary embodiment of the present invention.

Referring to FIG. 7, the coming-off prevention 32 formed on the side surface of the substrate supporting pin 31 may have a shape to surround the side surface of the substrate supporting pin 31. Further, the coming-off prevention unit 32 may have a ring shape, and may be integrated with the substrate supporting pin 31. The auxiliary unit 32a formed on the coming-off prevention unit 32 may be formed on a part of the coming-off prevention unit 32. However, in a deposition apparatus according to another exemplary embodiment of the present invention, the auxiliary unit 32a may be disposed in a shape to surround the substrate supporting pin 31, like the coming-off prevention unit 32. Although not illustrated in the drawing, the substrate supporting pin 31 may have a hole for inserting a rod therein.

Referring to FIG. 8, the coming-off prevention unit 32 formed on the side surface of the substrate supporting pin 31 may be formed on a part of the side surface of the substrate supporting pin 31. Further, the coming-off prevention unit 32 may have a rectangular plate shape. However, in a deposition apparatus according to another exemplary embodiment of the present invention, the coming-off prevention unit 32 may have various shapes, and may be disposed on at least a part of the side surface of the substrate supporting pin 31. Although not illustrated in the drawing, the substrate supporting pin 31 may have a hole for inserting a rod therein.

The shapes and arrangements of the substrate supporting pins and the coming-off prevention units in the deposition apparatuses according to the above-described exemplary embodiments are only examples for describing the present invention, and the present invention is not limited thereto, but may be modified in various manners.

While this invention has been described in connection with what is presently considered to be practical exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. A deposition apparatus comprising:
a substrate support;
a substrate supporting pin inserted into a hole formed in the substrate support;
a coming-off prevention unit formed on a side surface of the substrate supporting pin; and
a supporting plate supporting the substrate supporting pin.

2. The deposition apparatus of claim 1, wherein:
the coming-off prevention unit is disposed under the substrate support.

3. The deposition apparatus of claim 2, further comprising:
an auxiliary unit formed on the coming-off prevention unit.

4. The deposition apparatus of claim 3, wherein:
the auxiliary unit comprises an elastic body.

5. The deposition apparatus of claim 4, wherein:
the auxiliary unit comprises a spring.

6. The deposition apparatus of claim 3, wherein:
a hole is formed in the substrate supporting pin, and
a rod connected to the supporting plate is inserted into the hole of the substrate supporting pin.

7. The deposition apparatus of claim 6, further comprising:
a reaction chamber plate defining a reaction space together with the substrate support; and
a high-frequency connection terminal for supplying plasma power to the reaction chamber plate.

8. The deposition apparatus of claim 1, further comprising:
an auxiliary unit formed on the coming-off prevention unit.

9. The deposition apparatus of claim 8, wherein:
the auxiliary unit comprises an elastic body.

10. The deposition apparatus of claim 9, wherein:
the auxiliary unit comprises a spring.

11. The deposition apparatus of claim 8, wherein:
a hole is formed in the substrate supporting pin, and
a rod connected to the supporting plate is inserted into the hole of the substrate supporting pin.

12. The deposition apparatus of claim 11, further comprising:
a reaction chamber plate defining a reaction space together with the substrate support; and
a high-frequency connection terminal for supplying plasma power to the reaction chamber plate.

13. The deposition apparatus of claim 1, wherein:
a hole is formed in the substrate supporting pin, and
a rod connected to the supporting plate is inserted into the hole of the substrate supporting pin.

14. The deposition apparatus of claim 13, further comprising:
a reaction chamber plate defining a reaction space together with the substrate support; and
a high-frequency connection terminal for supplying plasma power to the reaction chamber plate.

15. The deposition apparatus of claim 1, further comprising:
a reaction chamber plate defining a reaction space together with the substrate support; and
a high-frequency connection terminal for supplying plasma power to the reaction chamber plate.
